(19) United States
(12) Patent Application Publication
(10) Pub. No.: US 2026/0213718 A1
(43) Pub. Date: Jul. 23, 2026

(54) OPERATIONAL TRANSCONDUCTANCE AMPLIFIER (OTA) WITH SEPARATE CASCODE PATHS FOR RECONFIGURABLE INPUT PAIRS

(71) Applicant: QUALCOMM Incorporated, San Diego, CA (US)

(72) Inventors: Xiaopeng ZHONG, Seattle, WA (US); Liang DAI, San Diego, CA (US)

(21) Appl. No.: 19/032,949

(22) Filed: Jan. 21, 2025

(51) Int. Cl. H03F 3/45

(52) U.S. Cl. CPC H03F 3/45219

(57) ABSTRACT

An OTA, including: a first input PFET including a gate configured to receive a first signal; a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation; a first cascode PFET coupled to the first set of one or more input PFETs, wherein the first cascode PFET is enabled in the first mode, and disabled in the second mode of operation; and a second cascode PFET coupled to the first input PFETs, wherein the second cascode PFET is disabled in the first mode of operation, and enabled in the second mode.

### FIELD

This disclosure relates generally to operational transconductance amplifiers (OTAs), and in particular, to an OTA with separate cascode paths for reconfigurable non-complementary or complementary input pair(s).

### BACKGROUND

An operational transconductance amplifier (OTA) is used in many applications to amplify an input single-ended or differential input voltage to generate a single-ended or differential output current, respectively. Often the OTA is used in applications that require amplification in a relatively low frequency range or bandwidth (e.g., 30 mega Hertz (MHz)) and in a relatively high frequency range or bandwidth (e.g., 1.5 giga Hertz (GHz)). In such wideband applications, two OTAs are typically employed: one that serves the low frequency range and another that serves the higher frequency range. However, due to high power consumption and large circuit or integrated circuit (IC) footprint, it may be preferred to have a single OTA capable of performing amplification when the input signal is in a low frequency range or in a high frequency range.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an operational transconductance amplifier (OTA). The OTA includes: a first input p-channel field effect transistor (PFET) including a gate configured to receive a first signal; a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation; a first cascode PFET coupled to the first set of one or more input PFETs, wherein the first cascode PFET is enabled in the first mode of operation, and disabled in the second mode of operation; and a second cascode PFET coupled to the first input PFET, wherein the second cascode PFET is disabled in the first mode of operation, and enabled in the second mode of operation.

Another aspect of the disclosure relates to an operational transconductance amplifier (OTA). The OTA includes: a first input p-channel field effect transistor (PFET) including a gate configured to receive a first signal; a second input n-channel field effect transistor (NFET) including a gate configured to receive the first signal; a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation; a first set of one or more input NFETs including a first set of one or more gates coupled to the gate of the first input NFET in the first mode of operation, wherein the first set of one or more gates of the first set of one or more input NFETs are decoupled from the gate of the first input NFET in the second mode of operation; a first cascode PFET including a source coupled between the first set of one or more input PFETs and the first set of one or more input NFETs, wherein the first cascode PFET is enabled in the first mode of operation, and disabled in the second mode of operation; and a second cascode PFET including a source coupled to the first input PFET in the first mode of operation and to both the first input PFET and the first input NFET in the second mode of operation, wherein the second cascode PFET is disabled in the first mode of operation, and enabled in the second mode of operation.

Another aspect of the disclosure relates to a method of generating a first output signal and a second output signal. The method includes: applying a first input signal to a first set of input field effect transistors (FETs) in a first mode of operation of an operational transconductance amplifier (OTA); coupling a first cascode FET to the first set of input FETs to generate the first output signal at a drain of the first cascode FET in the first mode of operation; applying a second input signal to a subset of one or more of the first set of input FETs in a second mode of operation of the OTA; and coupling a second cascode FET to the subset of one or more of the first set of input FETs to generate the second output signal at a drain of the second cascode FET in the second mode of operation.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a schematic diagram of an example operational transconductance amplifier (OTA) in a first configuration in accordance with an aspect of the disclosure.

FIG. 1B illustrates a schematic diagram of the example operational transconductance amplifier (OTA) of FIG. 1A in a second configuration in accordance with another aspect of the disclosure.

FIG. 2A illustrates a schematic diagram of another example operational transconductance amplifier (OTA) in a first configuration in accordance with another aspect of the disclosure.

FIG. 2B illustrates a schematic diagram of the example operational transconductance amplifier (OTA) of FIG. 2A in a second configuration in accordance with another aspect of the disclosure.

FIG. 3A illustrates a schematic diagram of another example operational transconductance amplifier (OTA) in a first configuration in accordance with another aspect of the disclosure.

FIG. 3B illustrates a schematic diagram of the example operational transconductance amplifier (OTA) of FIG. 3A in a second configuration in accordance with another aspect of the disclosure.

FIG. 4A illustrates a schematic diagram of another example operational transconductance amplifier (OTA) in a first configuration in accordance with another aspect of the disclosure.

FIG. 4B illustrates a schematic diagram of the example operational transconductance amplifier (OTA) of FIG. 4A in a second configuration in accordance with another aspect of the disclosure.

FIG. 5A illustrates a schematic diagram of another example operational transconductance amplifier (OTA) in a first configuration in accordance with another aspect of the disclosure.

FIG. 5B illustrates a schematic diagram of the example operational transconductance amplifier (OTA) of FIG. 5A in a second configuration in accordance with another aspect of the disclosure.

FIG. 6 illustrates a flow diagram of an example method of generating first and second output signals per first and second modes of operations in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

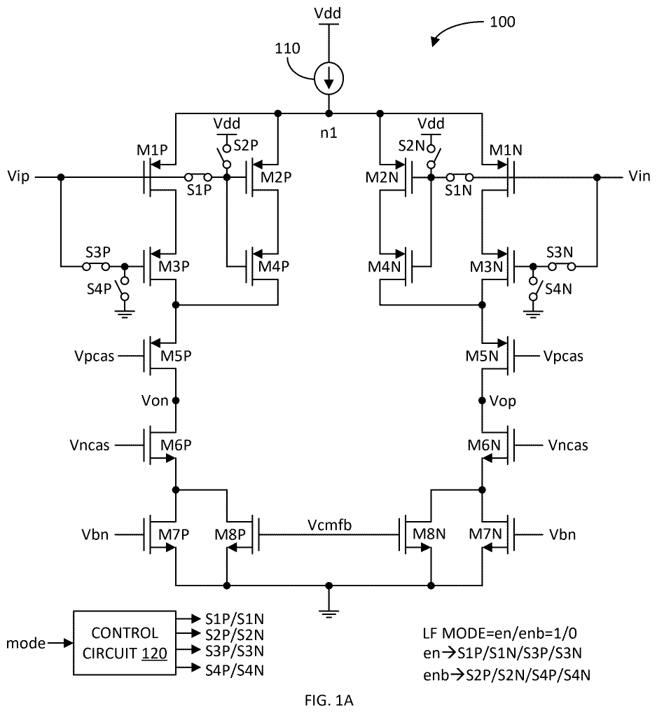

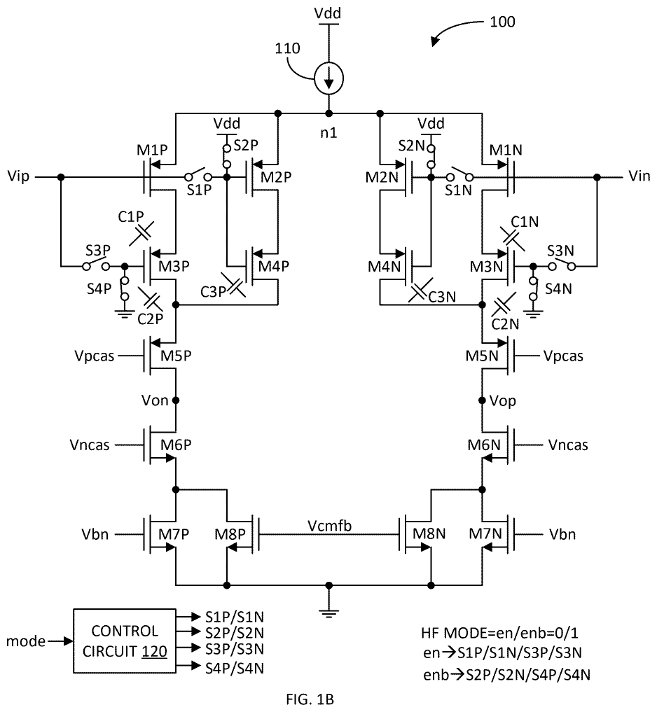

FIG. 1A illustrates a schematic diagram of an example operational transconductance amplifier (OTA) 100 in a first (e.g., low frequency (LF)) configuration in accordance with an aspect of the disclosure. The OTA 100 may be operated between first and second configurations. The first configuration may be used for relatively low frequency applications (e.g., 38 mega Hertz (MHz)) where 1/f flicker noise is larger. Flicker noise may be important because the input signal is located at the low frequency range, where 1/f noise is present. In the first configuration, the OTA 100 is configured to have an input differential field effect transistor (FET) pair with a programmable size of 4X to effectively remove the flicker noise because the flicker noise is mainly contributed by the input pair of the OTA. The second configuration may be used for relatively high bandwidth applications (e.g., 1.5 giga Hertz (GHz)). In the second configuration, the OTA 100 is configured to have an input differential FET pair with a programmable size of 1X to perform better in high bandwidth applications by reducing the gate parasitic capacitance connected to the input.

More specifically, the OTA 100 includes a current source 110 coupled between an upper voltage rail Vdd and a node n1. The OTA 100 further includes a positive-side (p-side or left-side) input p-channel field effect transistor (PFET) M1P coupled in series (in the source-to-drain direction) with a third reconfigurable p-side input PFET M3P and a p-side cascode PFET M5P between the node n1 and a negative differential output (Von) of the OTA 100. The OTA 100 further includes a second reconfigurable p-side input PFET M2P and a fourth reconfigurable p-side input PFET M4P coupled in series (in the source-to-drain direction) between the node n1 and a source of the p-side cascode PFET M5P. The p-side input PFET M1P includes a gate configured to receive a p-side differential input signal Vip. The p-side cascode PFET M5P includes a gate configured to receive a PFET cascode bias voltage Vpcas.

For reconfigurability between the first (LF) configuration and the second (HF) configuration, the OTA 100 includes p-side switching devices S1P, S2P, S3P, and S4P. The first p-side switching device S1P is coupled between the gate of the p-side input PFET M1P and gates of the second and fourth reconfigurable p-side input PFETs M2P and M4P, respectively. The second p-side switching device S2P is coupled between the upper voltage rail Vdd and the gates of the second and fourth reconfigurable p-side input PFETs M2P and M4P, respectively. The third p-side switching device S3P is coupled between the gate of the p-side input PFET M1P and a gate of the third reconfigurable p-side input PFET M3P. The fourth p-side switching device S4P is coupled between the gate of the third reconfigurable p-side input PFET M3P and a lower voltage rail (e.g., ground).

The OTA 100 further includes an output load circuit including p-side cascode n-channel field effect transistor (NFET) M6P and a p-side current source NFET M7P coupled in series (in the drain-to-source direction) between the negative differential output (Von) and the lower voltage rail. The p-side cascode NFET M6P includes a gate configured to receive an NFET cascode bias voltage Vncas. The p-side current source NFET M7P includes a gate configured to receive a current source bias voltage Vbn. The OTA 100 further includes a p-side common mode current source NFET M8P coupled in parallel with the p-side current source NFET M7P including drains coupled together, and sources coupled together and to the lower voltage rail. The p-side common mode current source NFET M8P includes a gate configured to receive a common mode feedback voltage Vcmfb related to the common mode voltage associated with the differential output Vop/Von of the OTA 100.

With regard to the negative-side (n-side or right-side), the OTA 100 includes an n-side input PFET M1N coupled in series (in the source-to-drain direction) with a third reconfigurable n-side input PFET M3N and an n-side cascode PFET M5N between the node n1 and the positive differential output (Vop) of the OTA 100. The OTA 100 further includes a second reconfigurable n-side input PFET M2N and a fourth reconfigurable n-side input PFET M4N coupled in series (in the source-to-drain direction) between the node n1 and a source of the n-side cascode PFET M5N. The n-side input PFET M1N includes a gate configured to receive an n-side differential input signal Vin. The n-side cascode PFET M5N includes a gate configured to receive the PFET cascode bias voltage Vpcas.

For reconfigurability between the first (LF) configuration and the second (HF) configuration, the OTA 100 includes n-side switching devices S1N, S2N, S3N, and S4N. The first n-side switching device S1N is coupled between the gate of the n-side input PFET M1N and gates of the second and fourth reconfigurable n-side input PFETs M2N and M4N, respectively. The second n-side switching device S2N is coupled between the upper voltage rail Vdd and the gates of the second and fourth reconfigurable n-side input PFETs M2N and M4N, respectively. The third n-side switching device S3N is coupled between the gate of the n-side input PFET M1N and a gate of the third reconfigurable n-side input PFET M3N. The fourth n-side switching device S4N is coupled between the gate of the third reconfigurable n-side input PFET M3N and the lower voltage rail (e.g., ground).

The output load circuit of the OTA 100 further includes: an n-side cascode NFET M6N and an n-side current source NFET M7N coupled in series (in the drain-to-source direction) between the positive differential output (Vop) and the lower voltage rail. The n-side cascode NFET M6N includes a gate configured to receive the NFET cascode bias voltage Vncas. The n-side current source NFET M7N includes a gate configured to receive the current source bias voltage Vbn. The output load circuit of the OTA 100 further includes an n-side common mode current source NFET M8N coupled in parallel with the n-side current source NFET M7N including drains coupled together, and sources coupled together and to the lower voltage rail. The n-side common mode current source NFET M8N includes a gate configured to receive the common mode feedback voltage Vcmfb related to the common mode voltage associated with the differential output Vop/Von of the OTA 100.

As discussed, the first configuration may be used in low frequency applications, where the input differential PFETs may have a relative size of 4X (e.g., where each PFET has a normalized size of substantially 1X). In this regard, the OTA 100 includes a control circuit 120 configured to receive a mode signal, and control the switching devices S1P/S1N, S2P/S2N, S3P/S3N, and S4P/S4N, respectively. For example, in response to the mode signal indicating low frequency (LF) mode, the control circuit 120 is configured to turn on (en=1) switching devices S1P/S1N/S3P/S3N and turn off (enb=0) switching devices S2P/S2N/S4P/S4N. This is summarized in the legend provided in FIG. 1A. In this configuration, the positive input differential signal Vip is provided directly to the gate of input PFET M1P, and indirectly to the gates of the reconfigurable input PFETs M2P/M4P and M3P via switching devices S1P and S3P to achieve a 4X p-side input PFET size, respectively; and the negative input differential signal Vin is provided directly to the gate of input PFET M1N, and indirectly to the gates of the reconfigurable input PFETs M2N/M4N and M3N via switching devices S1N and S3N to achieve a 4X n-side input PFET size, respectively.

FIG. 1B illustrates a schematic diagram of the example OTA 100 in the second (e.g., high frequency (HF)) configuration in accordance with another aspect of the disclosure. The second configuration may be used in high bandwidth or frequency applications, where the input differential PFETs may have a relative size of 1X (or smaller than the relative size in LF mode). In this regard, in response to the mode signal indicating high frequency (HF) mode, the control circuit 120 is configured to turn off (en=0) switching devices S1P/S1N/S3P/S3N and turn on (enb=1) switching devices S2P/S2N/S4P/S4N. This is summarized in the legend provided in FIG. 1B. In this configuration, the positive input differential signal Vip is only provided to the gate of the PFET M1P to achieve a 1X p-side input PFET size; and the negative input differential signal Vin is only provided to the gate of the PFET M1N to achieve a 1X n-side input PFET size. The upper voltage rail Vdd is coupled to the gates of PFETs M2P/M4P and M2N/M4N via switching devices S2P and S2N to turn off these devices, respectively. The lower voltage rail (e.g., ground) is coupled to the gates of PFETs M3P and M3N via switching devices S4P and S4N to fully turn on these devices to couple the input PFETs M1P/M1N to the cascode PFETs M5P/M5N, respectively.

An issue with the OTA 300 is that although PFETs M3P/M3N are fully turned on and the PFETs M4P/M4N are fully turned off in HF mode, there exists parasitic capacitance associated with these devices that may impact the high frequency performance of the OTA 100. For example, the turned-on PFETs M3P and M3N include gate-to-source parasitic capacitances C1P and C1N and gate-to-drain parasitic capacitance C2P/C2N that may impact the high frequency performance of the OTA 100 since they are coupled to the current paths through PFETs M1P/M3P/M5P and M1N/M3N/M5N, respectively. Further, the turned-off PFETs M4P and M4N include gate-to-drain capacitances C3P and C3N, which are also coupled to the current paths through PFETs M3P/M5P and M3N/M5N, respectively.

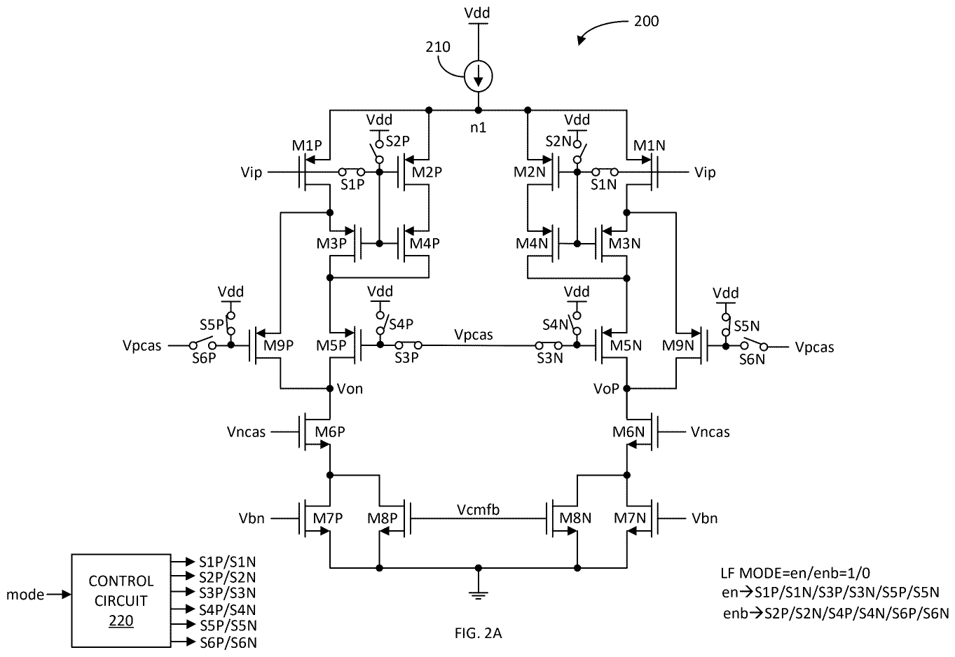

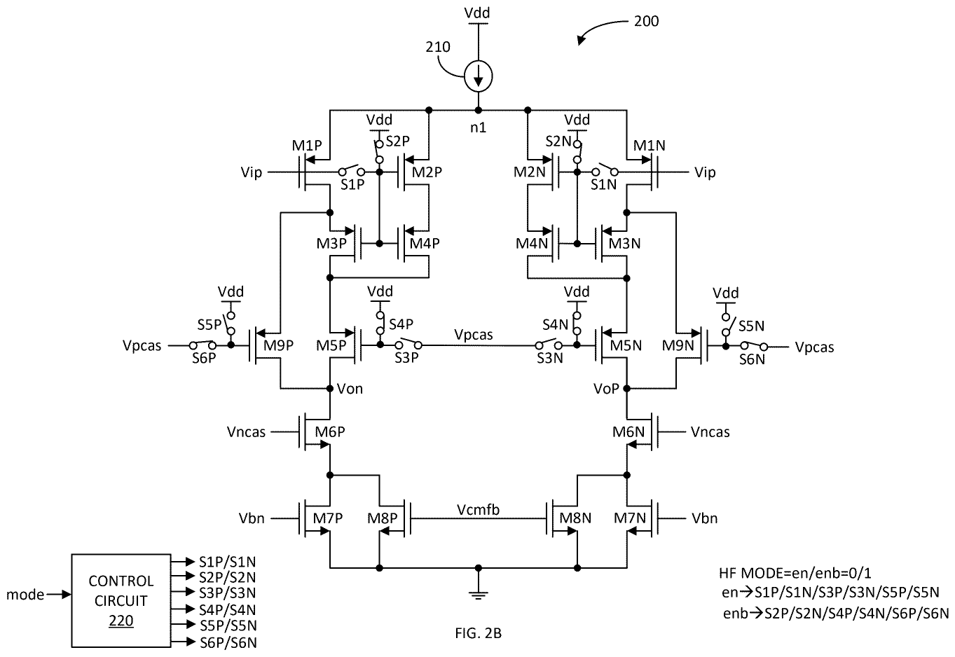

FIG. 2A illustrates a schematic diagram of another example operational transconductance amplifier (OTA) 200 in a first (e.g., low frequency (LF)) configuration in accordance with another aspect of the disclosure. The OTA 200 is similar to OTA 100 previously discussed in detail including many of the same/similar elements as indicated by the same reference identifiers and numbers with the exception that the most significant digit of the reference number is a “2” for OTA 200 instead of a “1” for OTA 100.

The OTA 200 differs from OTA 100 in that it includes cascode PFETs for HF mode that differ from the cascode PFETs for LF mode. The reason for the separate cascode PFETs for HF mode is that they are not subjected to as much parasitic capacitances due to turned-off input PFETs in LF mode. Accordingly, the high frequency performance of the OTA 200 is improved over the OTA 100 because it is less subjected to parasitic capacitances.

In particular, the OTA 100 includes p-side and n-side cascode PFETs M5P and M5N to be operational in accordance with LF mode. The OTA 100 further includes p-side and n-side cascode PFETs M9P and M9N to be operational in accordance with HF mode. For reconfigurability between LF mode and HF mode, the OTA 100 includes p-side switching devices S3P and S4P associated with the p-side LF cascode PFET M5P; n-side switching devices S3N and S4N associated with n-side LF cascode PFET M5N; switching devices S5P and S6P associated with p-side HF cascode PFET M9P; and switching devices S5N and S6N associated with n-side HF cascode PFET M9N.

In the first (LF) configuration, the control circuit 220, in response to the mode signal indicating LF mode, is configured to turn on (en=1) switching devices S1P/S1N and turn off (enb=0) switching devices S2P/S2N to collectively turn on reconfigurable input PFETs M2P-M4P/M2N-M4N to configure the differential input of the OTA 200 to an effective input differential PFET size of 4X. The control circuit 220, in response to the mode signal indicating LF mode, is also configured to turn on (en=1) switching devices S3P/S3N and turn off (enb=0) switching devices S4P/S4N to collectively turn on p-side and n-side LF cascode PFETs M5P and M5N. The control circuit 220, in response to the mode signal indicating LF mode, is further configured to turn on (en=1) switching devices S5P/S5N and turn off (enb=0) switching devices S6P/S6N to collectively turn off p-side and n-side HF cascode PFETs M9P/M9N. The first configuration of the OTA 200 is effectively the same as the first configuration of the OTA 100. The legend provided in FIG. 2A summarizes the aforementioned LF configuration.

FIG. 2B illustrates a schematic diagram of the example operational transconductance amplifier (OTA) 200 in a second (HF) configuration in accordance with another aspect of the disclosure. In the second (HF) configuration, the control circuit 220, in response to the mode signal indicating HF mode, is configured to turn off (en=0) switching devices S1P/S1N and turn on (enb=1) switching devices S2P/S2N to collectively turn off reconfigurable input PFETs M2P-M4P/M2N-M4N to configure the differential input of the OTA 200 to an effective input differential PFET size of 1X (namely PFETs M1P/M1N). The control circuit 220, in response to the mode signal indicating HF mode, is also configured to turn off (en=0) switching devices S3P/S3N and turn on (enb=1) switching devices S4P/S4N to collectively turn off p-side and n-side LF cascode PFETs M5P and M5N. The control circuit 220, in response to the mode signal indicating HF mode, is configured to turn off (en=0) switching devices S5P/S5N and turn on (enb=1) switching devices S6P/S6N to collectively turn on p-side and n-side HF cascode PFETs M9P/M9N. The legend provided in FIG. 2B summarizes the aforementioned HF configuration.

The second (HF) configuration of the OTA 200 is different than the second (HF) configuration of the OTA 100. In the case of OTA 200, it uses a different p-side and n-side cascode PFETs M9P/M9N, which is not subjected to the parasitic capacitance as the p-side and n-side cascode PFETs M5P/M5N of OTA 100. This is because the HF cascode PFETs M9P/M9N may be subjected to a lesser extend to source-to-gate capacitances of PFETs M3P/M3N and drain-to-gate capacitances of PFETs M5P/M5N. This is significantly less than the parasitic capacitances C1P/C1N/C2P/C2N and C3P/C3N of PFETs M3P/M3N and M4P and M4N in OTA 100, respectively. Accordingly, the OTA 200 may have better high frequency performance over OTA 100. As discussed further herein, the concept of having separate cascode PFETs for LF and HF modes may be applicable to other configurations of OTAs.

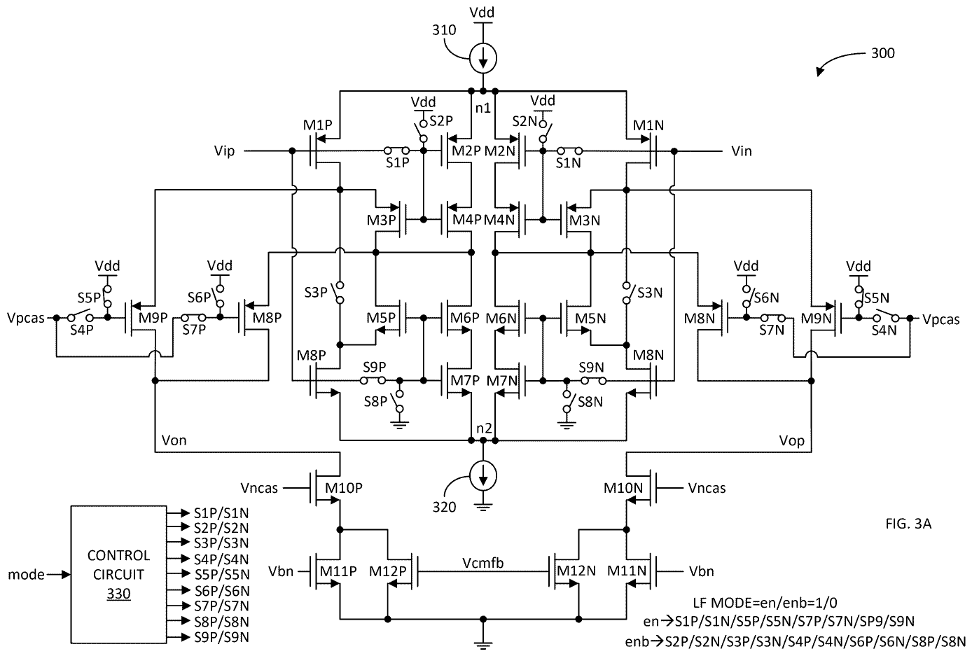

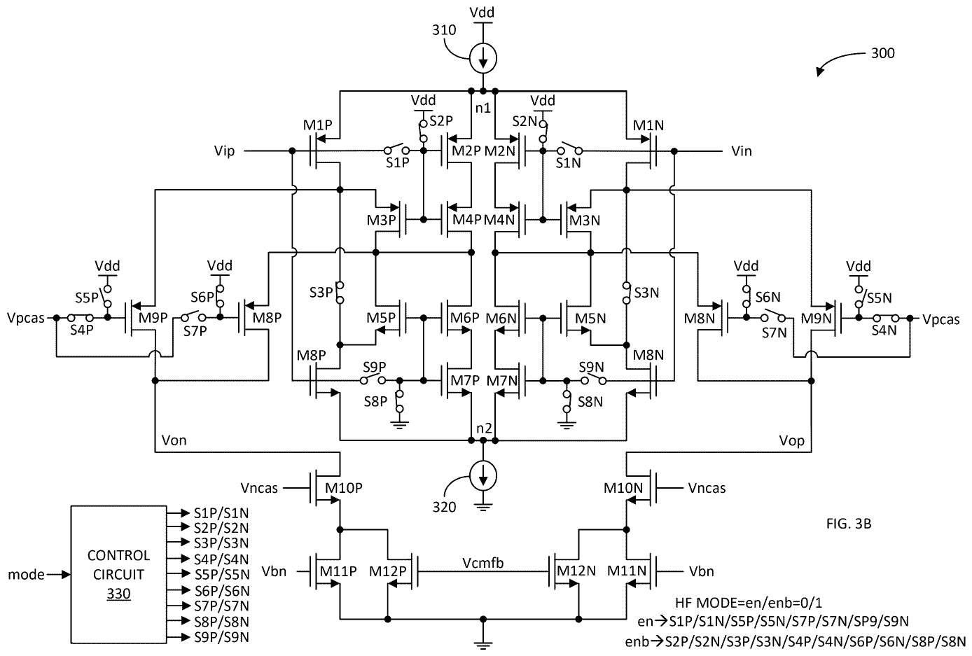

FIG. 3A illustrates a schematic diagram of another example operational transconductance amplifier (OTA) 300 in a first (e.g., low frequency (LF)) configuration in accordance with an aspect of the disclosure. The OTA 300 differs from OTA 200 in that it includes complementary input differential PFETs and NFETs to effectuate higher gain due to push-pull operations.

In particular, the OTA 300 includes a first current source 310 coupled between an upper voltage rail Vdd and a first node n1. The OTA 300 further includes a positive-side (p-side or left-side) input differential PFET M1P coupled in series (in the source-to-drain direction) with a p-side third switching device S3P and a p-side input differential NFET M8P (in the drain-to-source direction) between the first node n1 and a second node n2. The p-side input differential PFET M1P includes a gate coupled to a gate of the p-side input differential NFET M8P, both gates configured to receive a positive differential input signal Vip. The OTA 300 further includes a negative-side (n-side) input differential PFET M1N coupled in series (in the source-to-drain direction) with an n-side third switching device S3N and an n-side input differential NFET M8N (in the drain-to-source direction) between the first node n1 and the second node n2. The n-side input differential PFET M1N includes a gate coupled to a gate of the n-side input differential NFET M8N, both gates configured to receive a negative differential input signal Vin. The OTA 300 further includes a second current source 320 coupled between the second node n2 and a lower voltage rail (e.g., ground).

The OTA 300 further includes a second reconfigurable p-side input PFET M2P and a fourth reconfigurable p-side input PFET M4P both coupled in series (in the source-to-drain direction) with a sixth reconfigurable p-side input NFET M6P and a seventh reconfigurable p-side input NFET M7P (in the drain-to-source direction) between the first node n1 and the second node n2. The second and fourth reconfigurable p-side input PFETs M2P and M4P include gates coupled together. The sixth and seventh reconfigurable p-side input NFETs M6P and M7P include gates coupled together. The OTA 300 further includes a second reconfigurable n-side input PFET M2N and a fourth reconfigurable n-side input PFET M4N both coupled in series (in the source-to-drain direction) with a sixth reconfigurable n-side input NFET M6N and a seventh reconfigurable n-side input NFET M7N (in the drain-to-source direction) between the first node n1 and the second node n2. The second and fourth reconfigurable n-side input PFETs M2N and M4N include gates coupled together. The sixth and seventh reconfigurable n-side input NFETs M6N and M7N include gates coupled together.

The OTA 300 further includes a third reconfigurable p-side PFET M3P including a source coupled to the drain of the p-side input PFET M1P, a gate coupled to the gates of the second and fourth reconfigurable p-side input PFETs M2P and M4P, and a drain coupled to drains of the fifth and sixth reconfigurable p-side input NFETs M5P-M6P. The fifth reconfigurable p-side input NFET M5P includes a gate coupled to the gates of the sixth and seventh reconfigurable p-side input NFETs M6P and M7P, and a source coupled to a drain of the p-side input NFET M8P. The OTA 300 further includes a third reconfigurable n-side input PFET M3N including a source coupled to the drain of the n-side input PFET M1N, a gate coupled to the gates of the second and fourth reconfigurable n-side input PFETs M2N and M4N, and a drain coupled to drains of the fifth and sixth reconfigurable n-side input NFETs M5N-M6N. The fifth reconfigurable n-side input NFET M5N includes a gate coupled to the gates of the sixth and seventh reconfigurable n-side input NFETs M6N and M7N, and a source coupled to a drain of the n-side input NFET M8N.

For reconfigurability of the input FETs of the OTA 300, the OTA 300 includes switching devices S1P/S1N, S2P/S2N, S3P/S3N, S8P/S8N, and S9P/S9N. The switching device S1P is coupled between the gate of the p-side input PFET M1P and the gates of the second, third, and fourth reconfigurable p-side input PFETs M2P, M3P, and M4P, respectively. The switching device S2P is coupled between the upper voltage rail Vdd and the gates of the second, third, and fourth reconfigurable p-side input PFETs M2P, M3P, and M4P, respectively. The switching device S1N is coupled between the gate of the n-side input PFET M1N and the gates of the second, third, and fourth reconfigurable n-side input PFETs M2N, M3N, and M4N, respectively. The switching device S2N is coupled between the upper voltage rail Vdd and the gates of the second, third, and fourth reconfigurable n-side input PFETs M2N, M3N, and M4N, respectively.

With regard to the LF cascode PFETs, the OTA 300 includes a p-side LF cascode PFET M8P including a source coupled to the drains of the third and fourth reconfigurable p-side input PFETs M3P and M4P and the drains of the fifth and sixth reconfigurable p-side input NFETs M5P and M6P, respectively. The OTA 300 includes an n-side LF cascode PFET M8N including a source coupled to the drains of the third and fourth reconfigurable n-side input PFETs M3N and M4N and the drains of the fifth and sixth reconfigurable n-side input NFETs M5N and M6N, respectively.

With regard to the HF cascode PFETs, the OTA 300 includes a p-side HF cascode PFET M9P including a source coupled to the drain of the p-side input PFET M1P and the source of the third reconfigurable p-side input PFET M3P, respectively. The OTA 300 includes an n-side HF cascode PFET M9N including a source coupled to the drain of the n-side input PFET M1N and a source of the third reconfigurable n-side input PFET M3N, respectively. The p-side HF cascode PFET M9P includes a drain coupled to a drain of the p-side LF cascode PFET M8P, wherein the drains of PFETs M9P and M8P serve as the negative differential output (Von) of the OTA 300. Similarly, the n-side HF cascode PFET M9N includes a drain coupled to a drain of the n-side LF cascode PFET M8N, wherein the drains of PFETs M9N and M8N serve as the positive differential output (Vop) of the OTA 300.

For reconfigurability of the p-side cascode PFETs of the OTA 300, the OTA 300 includes switching devices S4P, S5P, S6P, and S7P. The switching device S4P is coupled between a source of the PFETs cascode bias voltage Vpcas and a gate of the p-side HF cascode PFET M9P. The switching device S5P is coupled between the upper voltage rail Vdd and the gate of the p-side HF cascode PFET M9P. The switching device S7P is coupled between the source of the PFET cascode bias voltage Vpcas and a gate of the p-side LF cascode PFET M8P. The switching device S6P is coupled between the upper voltage rail Vdd and the gate of the p-side LF cascode PFET M8P.

For reconfigurability of the n-side cascode PFETs of the OTA 300, the OTA 300 includes switching devices S4N, S5N, S6N, and S7N. The switching device S4N is coupled between the source of the PFET cascode bias voltage Vpcas and a gate of the n-side HF cascode PFET M9N. The switching device S5N is coupled between the upper voltage rail Vdd and the gate of the n-side HF cascode PFET M9N. The switching device S7N is coupled between the source of the PFET cascode bias voltage Vpcas and a gate of the n-side LF cascode PFET M8N. The switching device S7N is coupled between the upper voltage rail Vdd and the gate of the n-side LF cascode PFET M8N.

The OTA 300 further includes a p-side output load circuit including a p-side cascode NFET M10P and a p-side current source NFET M11P coupled in series (in the drain-to-source direction) between the negative differential output (Von) and the lower voltage rail. The p-side cascode NFET M10P includes a gate configured to receive an NFET cascode bias voltage Vncas. The p-side current source NFET M11P includes a gate configured to receive the current source bias voltage Vbn. The p-side output load circuit of the OTA 300 further includes a p-side common mode current source NFET M12P coupled in parallel with the p-side current source NFET M11P including drains coupled together, and sources coupled together and to the lower voltage rail. The p-side common mode current source NFET M12P includes a gate configured to receive a common mode feedback voltage Vcmfb related to the common mode voltage associated with the differential output Vop/Von of the OTA 300.

The OTA 300 further includes an n-side output load circuit including an n-side cascode NFET M10N and an n-side current source NFET M11N coupled in series (in the drain-to-source direction) between the positive differential output (Vop) and the lower voltage rail. The n-side cascode NFET M10N includes a gate configured to receive the NFET cascode bias voltage Vncas. The n-side current source NFET M11N includes a gate configured to receive the current source bias voltage Vbn. The n-side output load circuit of the OTA 300 further includes an n-side common mode current source NFET M12N coupled in parallel with the n-side current source NFET M11N including drains coupled together, and sources coupled together and to the lower voltage rail. The n-side common mode current source NFET M12N includes a gate configured to receive the common mode feedback voltage Vcmfb related to the common mode voltage associated with the differential output Vop/Von of the OTA 300.

In the first (LF) configuration, with regard to the input FETs, the control circuit 330, in response to the mode signal indicating LF mode, is configured to turn on (en=1) switching devices S1P/S1N and turn off (enb=0) switching devices S2P/S2N to collectively turn on input PFETs M2P-M4P/M2N-M4N to configure the differential input of the OTA 300 with an effective input differential PFET size of 4X (e.g., input PFETs M1P/M1N-M4P/M4N). Similarly, the control circuit 330, in response to the mode signal indicating LF mode, is configured to turn on (en=1) switching devices S9P/S9N and turn off (enb=0) switching devices S8P/S8N to collectively turn on input NFETs M5P-M7P/M5N-M7N to configure the differential input of the OTA 300 with an effective input differential NFET size of 4X (e.g., input NFETs M5P/M5N-M8P/M8N). Additionally, the control circuit 330, in response to the mode signal indicating LF mode, is configured to turn off (enb=0) switching devices S3P/S3N to decouple the drains of the input PFET M1P/M1N from the drains of the input NFET M8P/M8N, respectively. In this configuration, the input PFETs M1P-M1P/M1N-M4N and the input NFETs M5P/M5N-M8P/M8N operate in a push-pull manner with the input differential signal Vip/Vin to generate an amplified differential voltage at the respective inputs (sources) of the LF cascode PFETs M8P/M8N.

In the first (LF) configuration, with regard to the cascode PFETs M8P/M8N and M9P/M9N, the control circuit 330, in response to the mode signal indicating LF mode, is also configured to turn on (en=1) switching devices S7P/S7N and S5P/S5N and turn off (enb=0) switching devices S6P/S6N and S4P/S4N to collectively turn on the p-side and n-side LF cascode PFETs M8P and M8N and turn off the p-side and n-side HF cascode PFETs M9P/M9N, respectively. The legend provided in FIG. 3A summarizes the aforementioned LF configuration. The push-pull or complementary operations of the input PFETs M1P/M1N-M4P/M4N and input NFETs M5P/M5N-M8P/M8N including the operations of the LF cascode PFETs M5P/M5N and cascode NFETs M10P/M10N are configured to generate a differential output signal Vop/Von at the positive and negative differential outputs of the OTA 300 based on the input differential signal Vip/Vin applied to the input FETs M1P-M8P/M1N-M8N, respectively.

FIG. 3B illustrates a schematic diagram of the example operational transconductance amplifier (OTA) 300 in a second (e.g., high frequency (HF)) configuration in accordance with another aspect of the disclosure. In the second (HF) configuration, with regard to the input FETs, the control circuit 330, in response to the mode signal indicating HF mode, is configured to turn off (en=0) switching devices S1P/S1N and turn on (enb=1) switching devices S2P/S2N to collectively turn off input PFETs M2P-M4P/M2N-M4N to configure the differential input of the OTA 300 with an effective input differential PFET size of 1X (e.g., just input PFET M1P). Similarly, the control circuit 330, in response to the mode signal indicating HF mode, is configured to turn off (en=0) switching devices S9P/S9N and turn on (enb=1) switching devices S8P/S8N to collectively turn off input NFETs M5P-M7P/M5N-M7N to configure the differential input of the OTA 300 with an effective input differential NFET size of 1X (e.g., just input NFETs M8P/M8N). Additionally, the control circuit 330, in response to the mode signal indicating HF mode, is configured to turn on (enb=1) switching devices S3P/S3N to couple the drains of the input PFET M1P/M1N to the drains of input NFET M8P/M8N, respectively. The input PFETs M1P/M1N and the input NFETs M8P/M8N operate in a push-pull manner with the input differential signal Vip/Vin to generate an amplified differential voltage at the respective inputs (sources) of the HF cascode PFETs M9P/M9N.

In the second (HF) configuration, with regard to the cascode PFETs M8P/M8N and M9P/M9N, the control circuit 330, in response to the mode signal indicating HF mode, is also configured to turn off (en=0) switching devices S5P/S5N and S7P/S7N and turn on (enb=1) switching devices S4P/S4N and S6P/S6N to collectively turn on the p-side and n-side HF cascode PFETs M9P and M9N and turn off the p-side and n-side LF cascode PFETs M8P/M8N, respectively. The legend provided in FIG. 3B summarizes the aforementioned LF configuration. The push-pull or complementary operations of the input PFETs M1P/M1N and the input NFET M8P/M8N including the operations of the HF cascode PFETs M9P/M9N and cascode NFETs M10P/M10N area configured to generate a differential output signal Vop/Von at the positive and negative differential outputs of the OTA 300 based on the input differential signal Vip/Vin applied to the input FETs M1P and M8P/M1N and M8N, respectively.

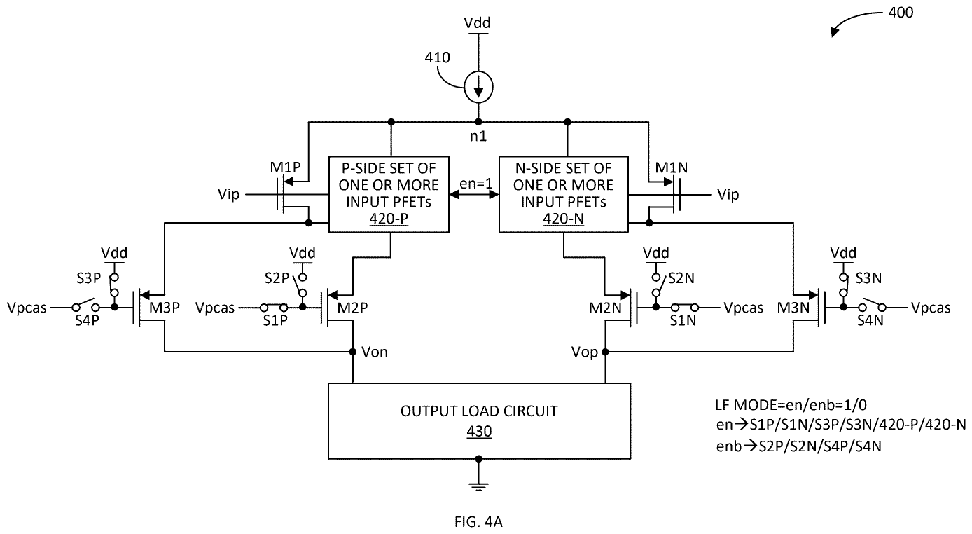

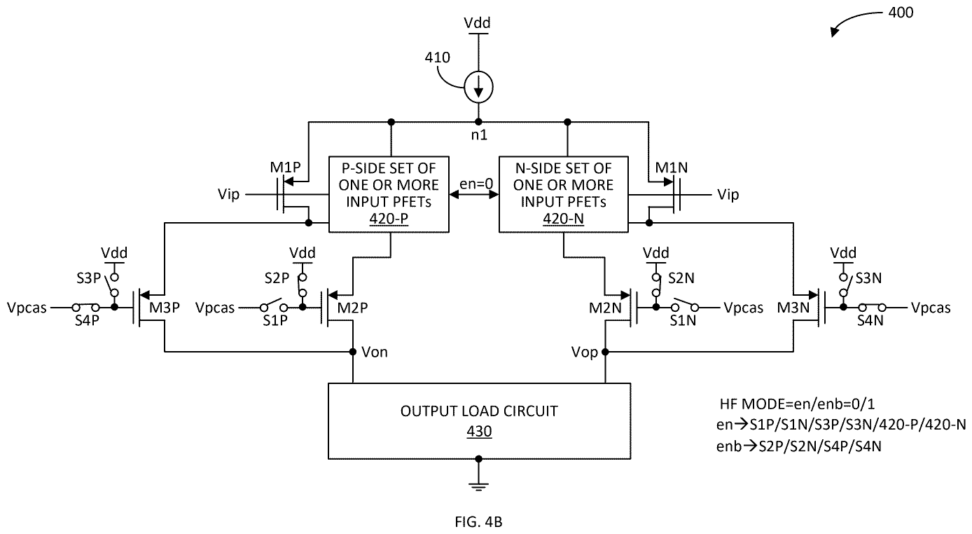

FIG. 4A illustrates a schematic diagram of another example operational transconductance amplifier (OTA) 400 in a first (low frequency (LF)) configuration in accordance with another aspect of the disclosure. The OTA 400 is a more general case of the non-complementary input pair OTA 200 previously discussed.

The OTA 400 includes a current source 410 coupled between an upper voltage rail Vdd and a node n1. The OTA 400 includes a p-side input PFET M1P coupled in series (in the source-to-drain direction) with a high frequency (HF) p-side cascode PFET M3P between node n1 and a negative differential output (Von) of the OTA 400. The OTA 400 includes an n-side input PFET M1N coupled in series (in the source-to-drain direction) with an HF n-side cascode PFET M3N between node n1 and a positive differential output (Vop) of the OTA 400. The p-side and n-side HF cascode PFETs M3P/M3N are disabled in LF mode by configuring switching devices S3P/S3N to close and couple Vdd to the gates of the p-side and n-side HF cascode PFETs M3P/M3N, and configuring switching devices S4P/S4N to open so that the PFET cascode bias voltage Vpcas is not applied to the gates of the p-side and n-side HF cascode PFETs M3P/M3N.

The OTA 400 further includes a p-side set of one or more input PFETs 420-P coupled in series (in the source-to-drain direction) with an p-side LF cascode PFET M2P between the node n1 (and/or the drain of p-side input PFET M1P) and the negative differential output (Von). The gates of the p-side set of one or more input PFETs 420-P are coupled to the gate of the p-side input PFET M1P based on an enable (en=1) signal in LF mode. The en signal (en=1) may enable the p-side set of one or more input PFETs 420-P in LF mode. The p-side LF cascode PFET M2P is enabled in LF mode by configuring switching device S2P to open to decouple Vdd from the gate of the p-side LF cascode PFET M2P, and configuring switching device S1P to close so that the PFET cascode bias voltage Vpcas is applied to the gate of the p-side LF cascode PFET M2P.

The OTA 400 further includes an n-side set of one or more input PFETs 420-N coupled in series (in the source-to-drain direction) with an n-side LF cascode PFET M2N between the node n1 (and/or the drain of n-side input PFET M1N) and the positive differential output (Vop). The gates of the n-side set of one or more input PFETs 420-N are coupled to the gate of the n-side input PFET M1N based on an enable (en=1) signal in LF mode. The en signal (en=1) may enable the n-side set of one or more input PFETs 420-N in LF mode. The n-side LF cascode PFET M2N is enabled in LF mode by configuring switching device S2N to open to decouple Vdd from the gate of the n-side LF cascode PFET M2N, and configuring switching device S1N to close so that the PFET cascode bias voltage Vpcas is applied to the gate of the n-side LF cascode PFET M2N.

The OTA 400 includes an output load circuit 430 coupled between the differential output Vop/Von of the OTA 400 and a lower voltage rail (e.g., ground). As per OTA 200, the output load circuit 430 may include p-side and n-side cascode NFETs, p-side and n-side current source NFETs, and p-side and n-side common mode current source NFETs. As previously discussed, the p-side and n-side cascode NFETs may be coupled in series with the p-side and n-side current source NFETs between the differential output Von/Vop of the OTA 400 and the lower voltage rail, respectively. The cascode NFETs may include gates configured to receive an NFET cascode bias voltage Vncas. The current source NFETs may include gates configured to receive a current source bias signal Vbn. The common mode current source NFETs may include gates configured to receive a common mode feedback voltage related to a common mode voltage associated with the differential output signal Vop/Von. It shall be understood that the output load circuit 430 may be implemented differently than the output load circuit of OTA 200.

FIG. 4B illustrates a schematic diagram of the example OTA 400 in a second (e.g., high frequency (HF)) configuration in accordance with another aspect of the disclosure. In the second (HF) configuration, the en signal (en=0) may disable the p-side and n-side sets of one or more input PFETs 420-P and 420-N so that the effective input PFET size of the OTA 400 in HF mode is less (e.g., a size of 1X) than the effective input PFET size (e.g., a size of 4X) of the OTA 400 in LF mode. With regard to the LF cascode PFETs M2P/M2N, the switching devices S2P/S2N are closed (e.g., enb=1) to couple the upper voltage rail Vdd to the gates of the LF cascode PFETs M2P/M2N to turn off these devices, and the switching devices S1P/S1N are open (e.g., en=0) so that the PFET cascode bias Vpcas is not applied to the gates of the LF cascode PFETs M2P/M2N. With regard to the HF cascode PFETs M3P/M3N, the switching devices S3P/S3N are open (e.g., en=0) to decouple the upper voltage rail Vdd from the gates of the HF cascode PFETs M3P/M3N to turn on these devices, and the switching devices S4P/S4N are closed (e.g., enb=1) so that the first cascode bias Vpcas is applied to the gates of the HF cascode PFETs M3P/M3N.

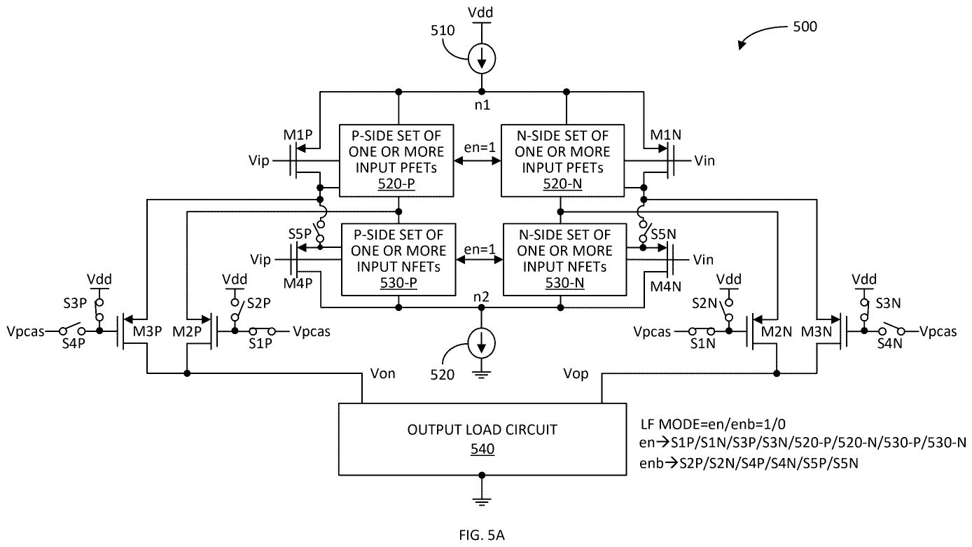

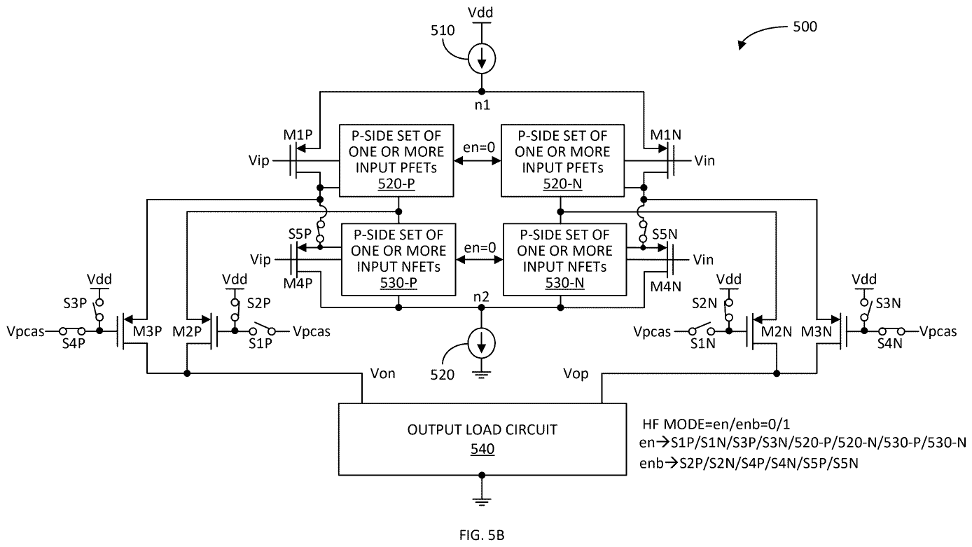

FIG. 5A illustrates a schematic diagram of another example operational transconductance amplifier (OTA) 500 in a first (low frequency (LF)) configuration in accordance with another aspect of the disclosure. The OTA 500 is a more general case of the complementary input pair OTA 300 previously discussed.

The OTA 500 includes a current source 510 coupled between an upper voltage rail Vdd and a node n1. The OTA 500 includes a p-side input PFET M1P coupled in series (in the source-to-drain direction) with a high frequency (HF) p-side cascode PFET M3P between node n1 and a negative differential output (Von) of the OTA 500. The OTA 500 includes an n-side input PFET M1N coupled in series (in the source-to-drain direction) with an HF n-side cascode PFET M3N between node n1 and a positive differential output (Vop) of the OTA 500. The p-side and n-side HF cascode PFETs M3P/M3N are disabled in LF mode by configuring switching devices S3P/S3N to close and couple Vdd to the gates of the p-side and n-side HF cascode PFETs M3P/M3N to turn off these devices, and configuring switching devices S4P/S4N to open so that the PFET cascode bias voltage Vpcas is not applied to the gates of the p-side and n-side HF cascode PFETs M3P/M3N.

The p-side input PFET M1P is also coupled in series (in the source-to-drain direction) with a fifth p-side switching device S5P and a p-side input NFET M4P (in the drain-to-source direction) between the first node n1 and a second node n2. The n-side input PFET M1N is also coupled in series (in the source-to-drain direction) with a fifth n-side switching device S5N and an n-side input NFET M4N (in the drain-to-source direction) between the first node n1 and the second node n2. The switching devices S5P/S5N are open (enb=0) in the LF mode. The OTA 500 further includes a second current source 520 coupled between the second node n2 and the lower voltage rail (e.g., ground).

The OTA 500 further includes a p-side set of one or more input PFETs 520-P coupled in series (in the source-to-drain direction) with a p-side set of one or more input NFETs 530-P (in the drain-to-source direction) between the first node n1 and a second node n2. The OTA 500 further includes an n-side set of one or more input PFETs 520-N coupled in series (in the source-to-drain direction) with an n-side set of one or more input NFETs 530-N (in the drain-to-source direction) between the first node n1 and a second node n2.

In LF mode, the p-side set of one or more input PFETs 520-P and the p-side set of one or more NFETs 530-P are all enabled (en=1) and have gates coupled to the gates of the p-side input PFET M1P and the p-side input NFET M4P, respectively. Also in LF mode, the n-side set of one or more input PFETs 520-N and the n-side set of one or more NFETs 530-N are all enabled (en=1) and have gates coupled to the gates of the n-side input PFET M1N and the n-side input NFET M4N, respectively. Accordingly, the OTA 500 have at least two complementary pairs of input transistors configured to perform push-pull operations in response to the input differential signal Vip/Vin.

The p-side LF cascode PFET M2P includes a source coupled to a node (drains) between the p-side one or more input PFETs 520-P and the p-side one or more input NFETs 530-P. Similarly, the n-side LF cascode PFET M2N includes a source coupled to a node (drains) between the n-side one or more input PFETs 520-N and the n-side one or more input NFETs 530-N. The p-side LF cascode PFET M2P includes a drain coupled to the negative differential output (Von), and the n-side LF cascode PFET M2N includes a drain coupled to the positive differential output (Vop). In LF mode, the switching devices S2P/S2N are open (enb=0) to decouple the upper voltage rail Vdd from the gates of the p-side and n-side LF cascode PFETs M2P/M2N allowing these devices to turn on. Also, in LF mode, the switching devices S1P/S1N are closed (en=1) so that the PFET cascode bias voltage Vpcas is applied to the gates of the p-side and n-side LF cascode PFETs M2P/M2N.

The OTA 500 includes an output load circuit 540 coupled between the differential output Vop/Von of the OTA 500 and a lower voltage rail (e.g., ground). As per OTA 300, the output load circuit 540 may include p-side and n-side cascode NFETs, p-side and n-side current source NFETs, and p-side and n-side common mode current source NFETs. As previously discussed, the p-side and n-side cascode NFETs may be coupled in series with the p-side and n-side current source NFETs between the differential output Von/Vop of the OTA 500 and the lower voltage rail, respectively. The cascode NFETs may include gates configured to receive an NFET cascode bias voltage Vncas. The current source NFETs may include gates configured to receive a current source bias signal Vbn. The common mode current source NFETs may include gates configured to receive a common mode feedback voltage related to a common mode voltage associated with the differential output signal Vop/Von of the OTA 500. It shall be understood that the output load circuit 540 may be implemented differently than the output load circuit of OTA 300.

FIG. 5B illustrates a schematic diagram of the example OTA 500 in a second (e.g., high frequency (HF)) configuration in accordance with another aspect of the disclosure. In the second (HF) configuration, the en signal (en=0) may disable the p-side and n-side sets of one or more input PFETs 520-P and 520-N and the p-side and n-side sets of one or more input NFETs 530-P and 530-N so that the effective complementary input PFET/NFET size of the OTA 500 in HF mode is less than the effective complementary input PFET/NFET size of the OTA 500 in LF mode (e.g., 1X<4X).

With regard to the LF cascode PFETs M2P/M2N, the switching devices S2P/S2N are closed (e.g., enb=1) to couple the upper voltage rail Vdd to the gates of the LF cascode PFETs M2P/M2N to turn off these devices, and the switching devices S1P/S1N are open (e.g., en=0) so that the PFET cascode bias Vpcas is not applied to the gates of the LF cascode PFETs M2P/M2N. With regard to the HF cascode PFETs M3P/M3N, the switching devices S3P/S3N are open (e.g., en=0) to decouple the upper voltage rail Vdd from the gates of the HF cascode PFETs M3P/M3N to turn on these devices, and the switching devices S4P/S4N are closed (e.g., enb=1) so that the PFET cascode bias Vpcas is applied to the gates of the HF cascode PFETs M3P/M3N. Additionally, the switching devices S5P/S5N are closed (enb=1) so that the drains of the input PFETs M1P/M1N are coupled to the drains of the complementary input NFETs M4P/M4N, respectively.

Although the previously discussed OTAs 100-500 have been described as differential OTAs, it shall be understood that each of the OTAs 100-500 may be configured as a single-ended OTAs (e.g., the n-side components need not be implemented or vice-versa).

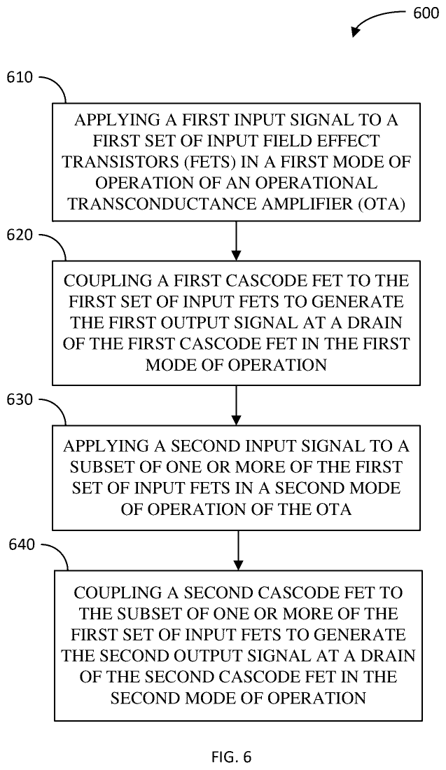

FIG. 6 illustrates a flow diagram of an example method of generating a first output signal and a second output signal in accordance with another aspect of the disclosure. The method includes: applying a first input signal to a first set of input field effect transistors (FETs) in a first mode of operation of an operational transconductance amplifier (OTA) (block 610); coupling a first cascode FET to the first set of input FETs to generate the first output signal at a drain of the first cascode FET in the first mode of operation (block 620); applying a second input signal to a subset of one or more of the first set of input FETs in a second mode of operation of the OTA (block 630); and coupling a second cascode FET to the subset of one or more of the first set of input FETs to generate the second output signal at a drain of the second cascode FET in the second mode of operation (block 640).

The following provides an overview of aspects of the present disclosure:

Aspect 1: An operational transconductance amplifier (OTA), comprising: a first input p-channel field effect transistor (PFET) including a gate configured to receive a first signal; a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation; a first cascode PFET coupled to the first set of one or more input PFETs, wherein the first cascode PFET is enabled in the first mode of operation, and disabled in the second mode of operation; and a second cascode PFET coupled to the first input PFET, wherein the second cascode PFET is disabled in the first mode of operation, and enabled in the second mode of operation.

Aspect 2: The OTA of aspect 1, wherein the second cascode PFET includes a source coupled to a drain of the first input PFET, and a drain coupled to a first output of the OTA.

Aspect 3: The OTA of aspect 1 or 2, further comprising a first switching device coupled between an upper voltage rail and a gate of the second cascode PFET, and a second switching device coupled between a source of a first cascode voltage and the gate of the second cascode PFET, wherein the first switching device is closed and the second switching device is open in the first mode of operation, and wherein the first switching device is open and the second switching device is closed in the second mode of operation.

Aspect 4: The OTA of any one of aspects 1-3, further comprising a first switching device coupled between an upper voltage rail and a gate of the first cascode PFET, and a second switching device coupled between a source of a first cascode voltage and the gate of the first PFET, wherein the first switching device is open and the second switching device is closed in the first mode of operation, and wherein the first switching device is closed and the second switching device is open in the second mode of operation.

Aspect 5: The OTA of any one of aspects 1-4, wherein the first set of one or more input PFETs includes a first PFET including a source coupled to the source of the first input PFET, and further comprising a first switching device coupled between the gate of the first input PFET and a gate of the first PFET, and a second switching device coupled between an upper voltage rail and the gate of the first PFET, wherein the first switching device is closed and the second switching device is open in the first mode of operation, and wherein the first switching device is open and the second switching device is closed in the second mode of operation.

Aspect 6: The OTA of aspect 5, wherein the first set of one or more input PFETs includes a second PFET including a source coupled to a drain of the first PFET, and a gate coupled to the gate of the first PFET.

Aspect 7: The OTA of aspect 6, wherein the first set of one or more input PFETs includes a third PFET coupled between the first input PFET and the first cascode PFET, wherein a gate of the PFET is coupled to the gates of the first and second PFETs.

Aspect 8: The OTA of any one of aspects 1-7, further comprising: a second input PFET including a gate configured to receive a second signal; a second set of one or more input PFETs including a second set of one or more gates coupled to the gate of the second input PFET in the first mode of operation, wherein the second set of one or more gates of the second set of one or more input PFETs are decoupled from the gate of the second input PFET in a second mode of operation; a third cascode PFET coupled to the second set of one or more input PFETs, wherein the third cascode PFET is enabled in the first mode of operation, and disabled in the second mode of operation; and a fourth cascode PFET coupled to the second input PFET, wherein the fourth cascode PFET is disabled in the first mode of operation, and enabled in the second mode of operation.

Aspect 9: The OTA of aspect 8, further comprising an output load circuit coupled between the first, second, third, and fourth cascode PFETs and a lower voltage rail.

Aspect 10: An operational transconductance amplifier (OTA), comprising: a first input p-channel field effect transistor (PFET) including a gate configured to receive a first signal; a second input n-channel field effect transistor (NFET) including a gate configured to receive the first signal; a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation; a first set of one or more input NFETs including a first set of one or more gates coupled to the gate of the first input NFET in the first mode of operation, wherein the first set of one or more gates of the first set of one or more input NFETs are decoupled from the gate of the first input NFET in the second mode of operation; a first cascode PFET including a source coupled between the first set of one or more input PFETs and the first set of one or more input NFETs, wherein the first cascode PFET is enabled in the first mode of operation, and disabled in the second mode of operation; and a second cascode PFET including a source coupled to the first input PFET in the first mode of operation and to both the first input PFET and the first input NFET in the second mode of operation, wherein the second cascode PFET is disabled in the first mode of operation, and enabled in the second mode of operation.

Aspect 11: The OTA of aspect 10, wherein the second cascode PFET includes a source coupled to a drain of the first input PFET in the first mode of operation, and coupled to a drain of the first input PFET and a drain of the first input NFET in the second mode of operation.

Aspect 12: The OTA of aspect 10 or 11, further comprising a first switching device coupled between an upper voltage rail and a gate of the second cascode PFET, and a second switching device coupled between a source of a first cascode voltage and the gate of the second cascode PFET, wherein the first switching device is closed and the second switching device is open in the first mode of operation, and wherein the first switching device is open and the second switching device is closed in the second mode of operation.

Aspect 13: The OTA of any one of aspects 10-12, further comprising a first switching device coupled between an upper voltage rail and a gate of the first cascode PFET, and a second switching device coupled between a source of a first cascode voltage and the gate of the first cascode PFET, wherein the first switching device is open and the second switching device is closed in the first mode of operation, and wherein the first switching device is closed and the second switching device is open in the second mode of operation.

Aspect 14: The OTA of any one of aspects 10-13, wherein the first set of one or more input PFETs includes a first PFET including a source coupled to the source of the first input PFET, and further comprising a first switching device coupled between the gate of the first input PFET and a gate of the first PFET, and a second switching device coupled between an upper voltage rail and the gate of the first PFET, wherein the first switching device is closed and the second switching device is open in the first mode of operation, and wherein the first switching device is open and the second switching device is closed in the second mode of operation.

Aspect 15: The OTA of aspect 14, wherein the first set of one or more input PFETs includes a second PFET including a source coupled to a drain of the first PFET, and a gate coupled to the gate of the first PFET.

Aspect 16: The OTA of aspect 15, wherein the first set of one or more input PFETs includes a third PFET including a source coupled to a drain of the first input PFET, a gate coupled to the gates of the first and second PFETs, and a drain coupled to a drain of the second PFET.

Aspect 17: The OTA of aspects 10-16, wherein the first set of one or more input NFETs includes a first NFET including a source coupled to the source of the first input NFET, and further comprising a first switching device coupled between the gate of the first input NFET and a gate of the first NFET, and a second switching device coupled between the gate of the first PFET and a lower voltage rail, wherein the first switching device is closed and the second switching device is open in the first mode of operation, and wherein the first switching device is open and the second switching device is closed in the second mode of operation.

Aspect 18: The OTA of aspect 17, wherein the first set of one or more input NFETs includes a second NFET including a source coupled to a drain of the first NFET, and a gate coupled to the gate of the first NFET.

Aspect 19: The OTA of aspect 18, wherein the first set of one or more input NFETs includes a third NFET including a source coupled to a drain of the first input NFET, a gate coupled to the gates of the first and second NFETs, and a drain coupled to a drain of the second NFET.

Aspect 20: A method of generating a first output signal and a second output signal, comprising: applying a first input signal to a first set of input field effect transistors (FETs) in a first mode of operation of an operational transconductance amplifier (OTA); coupling a first cascode FET to the first set of input FETs to generate the first output signal at a drain of the first cascode FET in the first mode of operation; applying a second input signal to a subset of one or more of the first set of input FETs in a second mode of operation of the OTA; and coupling a second cascode FET to the subset of one or more of the first set of input FETs to generate the second output signal at a drain of the second cascode FET in the second mode of operation.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An operational transconductance amplifier (OTA), comprising:
a first input p-channel field effect transistor (PFET) including a gate configured to receive a first signal;
a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation;
a first cascode PFET coupled to the first set of one or more input PFETs, wherein the first cascode PFET is enabled in the first mode of operation, and disabled in the second mode of operation; and
a second cascode PFET coupled to the first input PFET, wherein the second cascode PFET is disabled in the first mode of operation, and enabled in the second mode of operation.

2. The OTA of claim 1, wherein the second cascode PFET includes a source coupled to a drain of the first input PFET, and a drain coupled to a first output of the OTA.

3. The OTA of claim 1, further comprising a first switching device coupled between an upper voltage rail and a gate of the second cascode PFET, and a second switching device coupled between a source of a first cascode voltage and the gate of the second cascode PFET, wherein the first switching device is closed and the second switching device is open in the first mode of operation, and wherein the first switching device is open and the second switching device is closed in the second mode of operation.

4. The OTA of claim 1, further comprising a first switching device coupled between an upper voltage rail and a gate of the first cascode PFET, and a second switching device coupled between a source of a first cascode voltage and the gate of the first cascode PFET, wherein the first switching device is open and the second switching device is closed in the first mode of operation, and wherein the first switching device is closed and the second switching device is open in the second mode of operation.

5. The OTA of claim 1, wherein the first set of one or more input PFETs includes a first PFET including a source coupled to the source of the first input PFET, and further comprising a first switching device coupled between the gate of the first input PFET and a gate of the first PFET, and a second switching device coupled between an upper voltage rail and the gate of the first PFET, wherein the first switching device is closed and the second switching device is open in the first mode of operation, and wherein the first switching device is open and the second switching device is closed in the second mode of operation.

6. The OTA of claim 5, wherein the first set of one or more input PFETs includes a second PFET including a source coupled to a drain of the first PFET, and a gate coupled to the gate of the first PFET.

7. The OTA of claim 6, wherein the first set of one or more input PFETs includes a third PFET coupled between the first input PFET and the first cascode PFET, wherein a gate of the PFET is coupled to the gates of the first and second PFETs.

8. The OTA of claim 1, further comprising:
a second input PFET including a gate configured to receive a second signal;
a second set of one or more input PFETs including a second set of one or more gates coupled to the gate of the second input PFET in the first mode of operation, wherein the second set of one or more gates of the second set of one or more input PFETs are decoupled from the gate of the second input PFET in a second mode of operation;
a third cascode PFET coupled to the second set of one or more input PFETs, wherein the third cascode PFET is enabled in the first mode of operation, and disabled in the second mode of operation; and
a fourth cascode PFET coupled to the second input PFET, wherein the fourth cascode PFET is disabled in the first mode of operation, and enabled in the second mode of operation.

9. The OTA of claim 8, further comprising an output load circuit coupled between the first, second, third, and fourth cascode PFETs and a lower voltage rail.

10. An operational transconductance amplifier (OTA), comprising:
a first input p-channel field effect transistor (PFET) including a gate configured to receive a first signal;
a second input n-channel field effect transistor (NFET) including a gate configured to receive the first signal;
a first set of one or more input PFETs including a first set of one or more gates coupled to the gate of the first input PFET in a first mode of operation, wherein the first set of one or more gates of the first set of one or more input PFETs are decoupled from the gate of the first input PFET in a second mode of operation;
a first set of one or more input NFETs including a first set of one or more gates coupled to the gate of the first input NFET in the first mode of operation, wherein the first set of one or more gates of the first set of one or more input NFETs are decoupled from the gate of the first input NFET in the second mode of operation;
a first cascode PFET including a source coupled between the first set of one or more input PFETs and the first set of one or more input NFETs, wherein the first cascode PFET is enabled in the first mode of operation, and disabled in the second mode of operation; and
a second cascode PFET including a source coupled to the first input PFET in the first mode of operation and to both the first input PFET and the first input NFET in the second mode of operation, wherein the second cascode PFET is disabled in the first mode of operation, and enabled in the second mode of operation.

11. The OTA of claim 10, wherein the second cascode PFET includes a source coupled to a drain of the first input PFET in the first mode of operation, and coupled to a drain of the first input PFET and a drain of the first input NFET in the second mode of operation.

12. The OTA of claim 10, further comprising a first switching device coupled between an upper voltage rail and a gate of the second cascode PFET, and a second switching device coupled between a source of a first cascode voltage and the gate of the second cascode PFET, wherein the first switching device is closed and the second switching device is open in the first mode of operation, and wherein the first switching device is open and the second switching device is closed in the second mode of operation.

13. The OTA of claim 10, further comprising a first switching device coupled between an upper voltage rail and a gate of the first cascode PFET, and a second switching device coupled between a source of a first cascode voltage and the gate of the first cascode PFET, wherein the first switching device is open and the second switching device is closed in the first mode of operation, and wherein the first switching device is closed and the second switching device is open in the second mode of operation.

14. The OTA of claim 10, wherein the first set of one or more input PFETs includes a first PFET including a source coupled to the source of the first input PFET, and further comprising a first switching device coupled between the gate of the first input PFET and a gate of the first PFET, and a second switching device coupled between an upper voltage rail and the gate of the first PFET, wherein the first switching device is closed and the second switching device is open in the first mode of operation, and wherein the first switching device is open and the second switching device is closed in the second mode of operation.

15. The OTA of claim 14, wherein the first set of one or more input PFETs includes a second PFET including a source coupled to a drain of the first PFET, and a gate coupled to the gate of the first PFET.

16. The OTA of claim 15, wherein the first set of one or more input PFETs includes a third PFET including a source coupled to a drain of the first input PFET, a gate coupled to the gates of the first and second PFETs, and a drain coupled to a drain of the second PFET.

17. The OTA of claim 10, wherein the first set of one or more input NFETs includes a first NFET including a source coupled to the source of the first input NFET, and further comprising a first switching device coupled between the gate of the first input NFET and a gate of the first NFET, and a second switching device coupled between the gate of the first PFET and a lower voltage rail, wherein the first switching device is closed and the second switching device is open in the first mode of operation, and wherein the first switching device is open and the second switching device is closed in the second mode of operation.

18. The OTA of claim 17, wherein the first set of one or more input NFETs includes a second NFET including a source coupled to a drain of the first NFET, and a gate coupled to the gate of the first NFET.

19. The OTA of claim 18, wherein the first set of one or more input NFETs includes a third NFET including a source coupled to a drain of the first input NFET, a gate coupled to the gates of the first and second NFETs, and a drain coupled to a drain of the second NFET.

20. A method of generating a first output signal and a second output signal, comprising:
applying a first input signal to a first set of input field effect transistors (FETs) in a first mode of operation of an operational transconductance amplifier (OTA);
coupling a first cascode FET to the first set of input FETs to generate the first output signal at a drain of the first cascode FET in the first mode of operation;
applying a second input signal to a subset of one or more of the first set of input FETs in a second mode of operation of the OTA; and
coupling a second cascode FET to the subset of one or more of the first set of input FETs to generate the second output signal at a drain of the second cascode FET in the second mode of operation.
